(19) United States
(12) Patent Application Publication
(10) Pub. No.: US 2010/0210116 A1
(43) Pub. Date: Aug. 19, 2010

(54) METHODS OF FORMING VAPOR THIN FILMS AND SEMICONDUCTOR INTEGRATED CIRCUIT DEVICES INCLUDING THE SAME

(75) Inventors: Jae-Young AHN, Seongnam-si (KR); Ki-Hyun Hwang, Seongnam-si (KR); Young-Geun Park, Suwon-si (KR); Jun-Kyu Yang, Seoul (KR); Byong-Sun Ju, Seongnam-si (KR); Dong-Woon Shin, Seongnam-si (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/704,299

(22) Filed: Feb. 11, 2010

(30) Foreign Application Priority Data
Feb. 16, 2009 (KR) 10-2009-0012496

(51) Int. Cl. H01L 21/461

(52) U.S. Cl. 438/761; 438/758; 257/E21.483

(57) ABSTRACT

A method of forming a vapor thin film is provided, which includes loading a substrate into a chamber, adsorbing a source gas on the substrate by supplying the source gas into the chamber, and forming the thin film on the substrate by supplying a reaction gas into the chamber, wherein the forming of the thin film on the substrate is proceeded under an electric field formed in one direction on the substrate by applying a bias to the substrate.

### CROSS-REFERENCE TO RELATED APPLICATIONS

This application is based on and claims priority from Korean Patent Application No. 10-2009-0012496, filed on Feb. 16, 2009 in the Korean Intellectual Property Office, the disclosure of which is incorporated herein in its entirety by reference.

### BACKGROUND

1. Field of the Invention

The present invention relates to the field of semiconductors, and more particularly, to methods of forming films in semiconductor devices.

2. Description of the Prior Art

It is known to use a process, such as physical vapor deposition (PVD), chemical vapor deposition (CVD), atomic layer deposition (ALD), or the like, to form thin films on a semiconductor substrate. ALD can form a thin film by supplying gases in independent pulses in a time sharing manner rather than simultaneously supplying the gases. For example, a thin film can be formed using ALD to have a thickness of the atomic layer by alternately supplying a source gas, a purge gas, a reactant gas, and a purge gas. According to the ALD method, the step coverage of the thin film can be superior, and the thin film can be formed over a large area with a substantially uniform thickness. Also, by adjusting the number of repetitions in forming the thin film, the thickness of the thin film can be finely adjusted.

On the other hand, as the semiconductor device is refined and miniaturized, it frequently occurs to fill a region having a large aspect ratio with a thin film. However as the aspect ratio becomes larger, it may be more difficult to fill the region without creating a void.

### SUMMARY

In some aspects of the present invention, there is provided a method of forming a thin film, which can include supplying a source gas to a chamber containing a substrate to adsorb the source gas on the substrate, applying an electric field in the chamber in a direction across the substrate, and supplying a reaction gas to the chamber to form a thin film on the substrate under influence of the electric field.

In other aspects of the present invention, there is provided a method of fabricating a semiconductor integrated circuit device, which can include forming a thin film using the method of forming a thin film and, further, forming on the thin film at least one selected from the group consisting of a HDP (High Density Plasma) layer, a FOX (Flowable Oxide) layer, a TOSZ (Tonen SilaZene) layer, a SOG (Spin On Glass) layer, a USG (Undoped Silica Glass) layer, a TEOS (Tetraethyl Ortho Silicate) layer, and an LTO (Low Temperature Oxide) layer, or a combination thereof.

### BRIEF DESCRIPTION OF THE DRAWINGS

FIG. 1 is a flowchart illustrating methods of forming a thin film according to embodiments of the present invention;

FIG. 2 is a timing diagram describing methods of forming a thin film according to embodiments of the present invention;

FIG. 3 is a view describing thin film deposition in a region having a large aspect ratio;

FIG. 4 is a graph showing a difference in deposition rate in accordance with a region of FIG. 3; and

FIG. 5 is a view illustrating a thin film structure formed in accordance with a method of forming a thin film and a method of fabricating a semiconductor integrated circuit device according to embodiments of the present invention.

### DETAILED DESCRIPTION OF THE EMBODIMENTS

While the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention as defined by the claims.

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

Hereinafter, a method of forming a thin film according to an embodiment of the present invention will be described.

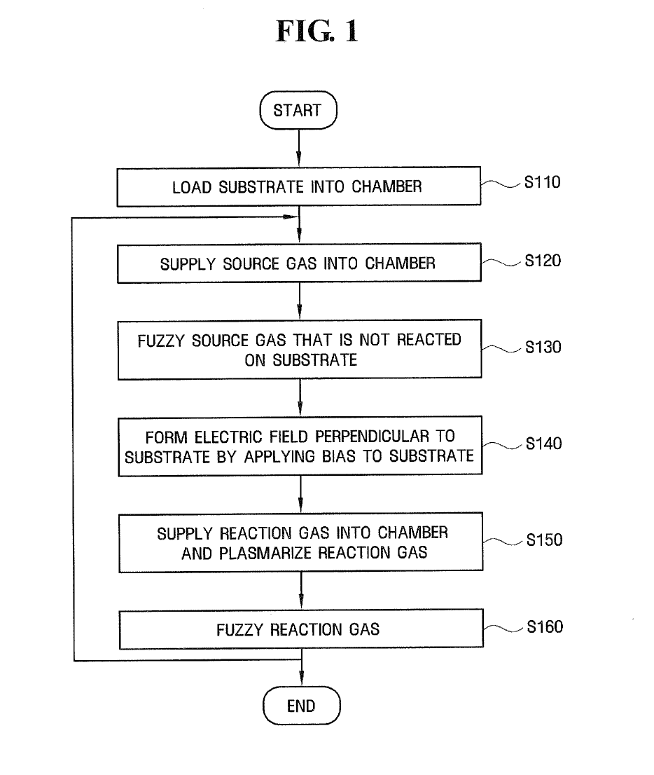

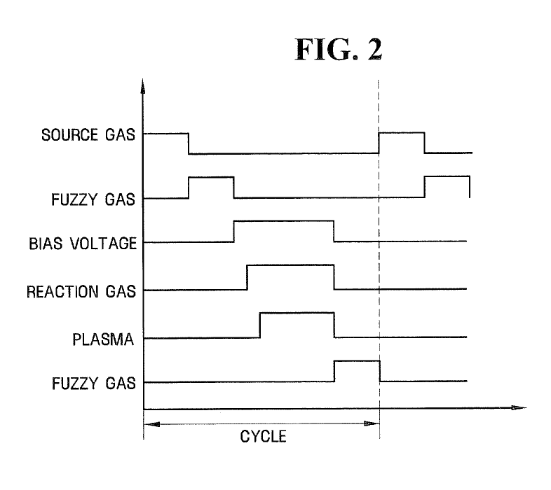

FIG. 1 is a flowchart illustrating a method of forming a thin film according to an embodiment of the present invention, and FIG. 2 is a timing diagram explaining a method of forming a thin film according to an embodiment of the present invention.

Referring to FIGS. 1 and 2, a substrate is loaded into a chamber of an atomic layer deposition (ALD) device S110.

On the substrate, diverse constituent elements for constituting a semiconductor integrated circuit may be formed. Also, processes up to the stage before a thin film is formed in the ALD device may have been completed. The thin film to be formed on the substrate, for example, may be a shallow trench isolation (STI) region, an interlayer dielectric (ILD) layer, an inter-metal dielectric (IMD) layer, and the like. Also, a region in which the thin film is formed on the substrate may be a region having a large aspect ratio.

Then, a source gas is supplied into the chamber S120. If the source gas is supplied into the chamber for a predetermined time, part of the source gas is reacted or adsorbed on the surface of the substrate, and the remaining gas is physically adsorbed on the surface of the reacted or adsorbed source gas or stays in the chamber.

In this case, an inactive gas may be supplied together with the source gas. The inactive gas may be, for example, Ar, He, Kr, Xe, or a combination thereof.

The source gas may differ in accordance with the kind of the thin film to be formed. For example, in the case of forming an oxide layer, a source gas may be supplied in addition to an oxide reaction gas. For example, in the case of forming SiO₂, a silicon source gas may be supplied. The silicon source gas may be one selected from the group consisting of SiH₄, Si₂H₆, Si₃H₈, SiH₂Cl₂, SiCl₄, Si₂Cl₆, and BTBAS, or a combination thereof.

Then, the source gas, which has not been adsorbed or reacted on the substrate, is fuzzied S130. Fuzzying the source gas may be performed by supplying a fuzzy gas. An inactive gas, which has not participated in the corresponding reaction, may be used as the fuzzy gas, and the inactive gas may be, for example, Ar, He, Kr, Ze, or a combination thereof. On the other hand, the source gas may be fuzzied out in a compulsory exhausting method, e.g. by pumping, rather than in a diffusion method. Simultaneously with the fuzzy gas supply and pumping, the source gas may also be fuzzied.

Then, an electric field that is perpendicular to the substrate is formed by applying a bias to the substrate S140. Applying a bias to the substrate may be performed in diverse methods, and a DC bias may be applied to the substrate. For example, electrodes may be mounted on upper and lower parts of the chamber, and the bias applied between the electrodes to form the electric field that is perpendicular to the substrate. Also, the electric field that is perpendicular to the substrate may also be formed by applying the bias between upper and lower parts of a chuck mounted on the substrate. The direction of the electric field may differ in accordance with the supplied reaction gas and the kind of the thin film to be formed. In some embodiments, in the case in which an oxygen reaction gas is supplied and plasmarized, O+ may be formed, and thus an electric field is formed so that the lower part of the substrate has a negative polarity and the upper part of the substrate has a positive electrode.

Then, a reaction gas is supplied into the chamber to be plasmarized S150. In forming the plasma, the reaction gas can be plasmarized by applying an RF power or a DC power to the chamber into which the reaction gas is supplied.

In a state in which the electric field is formed perpendicular to the substrate, a second source gas or reaction gas is supplied and plasmarized (hereinafter, in the description of the invention, the second source gas or reaction gas at this state is commonly called a reaction gas). First, a reaction gas is supplied into the chamber. In the case of forming an oxide layer, an oxide reaction gas may be a gas including oxygen, a gas having an oxidation power, or a combination thereof, e.g. may be one selected from the group consisting of O₂, O₃, H₂O, NO, and N₂O, or a combination thereof. After the injection of the corresponding gas, plasma of the reaction gas can be formed by supplying the plasma power to a reactor. In some embodiments according to the present invention, all gases capable of forming an oxide layer are commonly called oxide reaction gases.

Once the oxide reaction gas is supplied and plasmarized, plasma, which includes oxygen positive ions O+ and oxygen radicals O* in an unstable excited state, is formed. Here, the oxygen position ions and the oxygen radicals, which are all generated by plasma, have high reactivity.

The oxygen positive ions are under the electric field formed perpendicular to the substrate. In the case in which the electric field is formed so that the lower part of the substrate becomes a negative electrode, the oxygen positive ions are forced in a direction of the substrate, the region that is perpendicular to the direction of the electric field, i.e. the region that is substantially parallel to the substrate, is more influenced by the polarized particles generated by the plasma in comparison to the region that is perpendicular to the substrate. By contrast, since the oxygen radicals are neutral, they exert a uniform influence upon the whole region of the substrate regardless of the electric field of the substrate.

Consequently, in a region that is perpendicular to the direction of the electric field, i.e. in a region that is parallel to the substrate, both the oxygen radicals and the oxygen positive ions exert a great influence upon the deposition rate, whereas in a region of the substrate having a large slope against the direction of the substrate, the oxygen radicals substantially exert an influence upon the deposition rate. Here, the term “substantially” does not mean that the oxygen positive ions are not entirely deposited on a region having a large slope against the direction of the substrate. However, in depositing the oxygen positive ions on regions of the substrate, the deposition rate in the region that is parallel to the substrate is greater than that in the region having a large slope against the direction of the substrate, and thus it can be considered that most oxygen positive ions are deposited on the region that is parallel to the substrate.

As described above, it is exemplified that the reaction gas is supplied after the electric field is formed. However, the supply of the reaction gas according to the present invention is not limited thereto, and the electric filed may be formed after the reaction gas is supplied. It is also possible to form the electric field while the reaction gas is being supplied.

Then, the non-reacted oxide reaction gas is fuzzied S160. By properly repeating S120 to S160, a thin film with a desired thickness can be deposited.

On the other hand, on the thin film formed using the ALD method, at least one selected from the group consisting of a HDP (High Density Plasma) layer, a FOX (Flowable Oxide) layer, a TOSZ (Tonen SilaZene) layer, an SOG (Spin On Glass) layer, a USG (Undoped Silica Glass) layer, a TEOS (Tetraethyl Ortho Silicate) layer, and an LTO (Low Temperature Oxide) layer, or a combination thereof may be further formed. That is, the whole film to be formed is not formed only in the ALD method, but part of the film material is formed in the ALD method, and the remaining film material is formed in another method.

As described above, in an embodiment of the present invention, it is exemplified that the electric field is formed in a direction perpendicular to the substrate. However, it is apparent that the direction of the electric power can be adjusted for more efficient deposition.

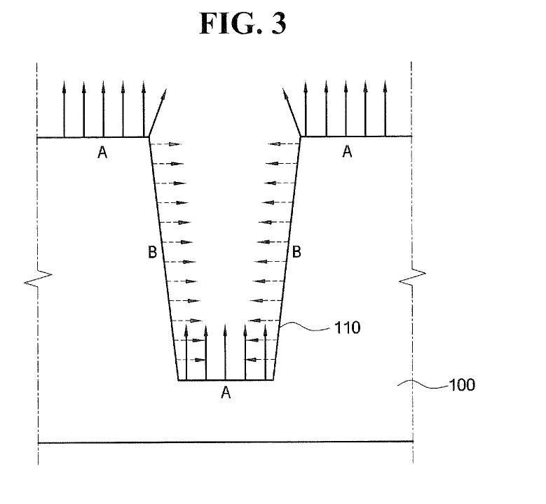

Hereinafter, with reference to FIGS. 3 to 5, the effect of the method of forming a thin film according to an embodiment of the present invention will be described in detail.

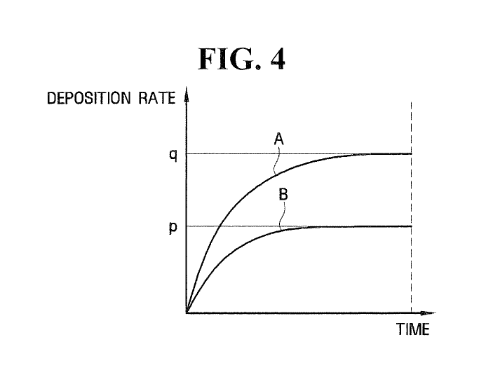

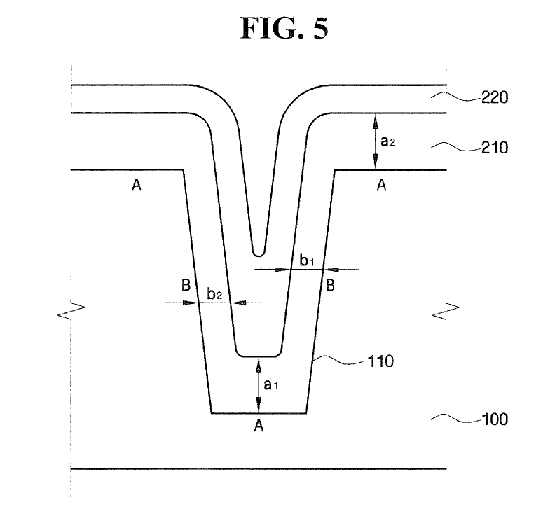

FIG. 3 is a view explaining thin film deposition in a region having a large aspect ratio, and FIG. 4 is a graph showing a difference in deposition rate in accordance with a region of FIG. 3. FIG. 5 is a view illustrating a thin film structure finally formed in accordance with a method of forming a thin film and a method of fabricating a semiconductor integrated circuit device according to an embodiment of the present invention.

Referring to FIG. 3, a trench 110 having a large aspect ratio is formed on the substrate 100, and a thin film is deposited on an inner surface of the trench 110 and the substrate 100. In this case, a region A indicates a region that is parallel to the substrate 100, and arrows in solid lines indicate a deposition speed in the region A. A region B indicates a region having a large slope against the direction of the substrate 100, and arrows in dotted lines indicate a deposition speed in the region B. Referring to FIG. 3, the deposition speed in the region that is parallel to the substrate 100 is higher than the deposition speed in the region having a large slope against the direction of the substrate 100. This is because both the oxygen radicals and the oxygen position ions exert a great influence upon the deposition speed in the region A, while only the oxygen radicals exert a great influence upon the deposition speed in the region B.

FIG. 4 is a graph showing the thin film deposition rates in regions A and B. Since the oxygen radicals and the oxygen position ions are simultaneously deposited on the region A, but only the oxygen radicals are deposited on the region B, the deposition rates in the regions A and B differ greatly. That is, the deposition rate in the region A for a predetermined time is q, whereas the deposition rate in the region B is p, which is greatly smaller than the deposition rate q in the region A.

Referring to FIG. 5, a first thin film 210, which is formed in the thin film forming method, is formed on the substrate 100 on which the trench 110 is formed. A second thin film 220 formed on an upper part of the first thin film 210 may be a thin film formed in the ALD method, or may be a thin film formed in another method, e.g. an HDP layer, a FOX layer, a TOSZ layer, a USG layer, or the like.

In FIG. 5, it can be seen that in forming the first thin film 210, the thicknesses a1 and a2 of the thin film formed on the region A are greatly larger than the thicknesses b1 and b2 of the thin film formed on the region B.

According to embodiments of the present invention, the deposition rate in the region A that is parallel to the substrate 100 is greater than the deposition rate in the region B that has a large slope against the direction of the substrate 100. Accordingly, in forming the thin film that fills the trench isolation region having a large aspect ratio or a gap between fine patterns, the occurrence of voids can be reduced in the thin film, and thus the filling work can be done more efficiently. Also, in forming an interlayer dielectric layer or inter-metal dielectric layer of a high-integrated device, the gap between the fine patterns can be efficiently filled, and thus the reliability of the semiconductor integrated circuit device can be improved.

According to the method of foaming a thin film or the method of fabricating a semiconductor integrated circuit device according to an embodiment of the present invention, the thin film is deposited by properly performing the ALD method and another thin film deposition method at the same time, the characteristic and the productivity of the thin film can be improved.

Although preferred embodiments of the present invention have been described for illustrative purposes, those skilled in the art will appreciate that various modifications, additions and substitutions are possible, without departing from the scope and spirit of the invention as disclosed in the accompanying claims.

What is claimed:

1. A method of forming a thin film, comprising:
supplying a source gas to a chamber containing a substrate to adsorb the source gas on the substrate;
applying an electric field in the chamber in a direction across the substrate; and
supplying a reaction gas to the chamber to form a thin film on the substrate under influence of the electric field.

2. The method of claim 1, further comprising:
fuzzying the source gas and/or the reaction gas in the chamber after adsorbing the source gas on the substrate by supplying the source gas into the chamber, or after forming the thin film on the substrate by supplying the reaction gas into the chamber.

3. The method of claim 1, wherein the method of forming the thin film comprises atomic layer deposition (ALD).

4. The method of claim 1, wherein the source gas comprises silicon.

5. The method of claim 4, wherein the source gas is one selected from the group consisting of SiH₄, Si₂H₆, Si₃H₈, SiH₂Cl₂, SiCl₄, Si₂Cl₆, and BTBAS, or a combination thereof.

6. The method of claim 1, wherein the reaction gas comprises an oxide reaction gas.

7. The method of claim 6, wherein the oxide reaction gas is one selected from the group consisting of O₂, O₃, H₂O, NO, and N₂O, or a combination thereof.

8. The method of claim 6, wherein oxygen radicals and oxygen positive ions are generated by plasmarizing the oxide reaction gas, and the reaction and deposition of the oxygen radicals and the oxygen positive ions in a substrate region that is perpendicular to the electric field is greater than those in a substrate region that is parallel to the electric field.

9. The method of claim 1, wherein in forming the thin film, the deposition rate in a substrate region that is perpendicular to one direction on the substrate is set to be higher than the deposition rate in a substrate region that is parallel to the one direction.

10. A method of according to claim 1 further comprising:
forming, on the thin film, at least one selected from the group consisting of a HDP (High Density Plasma) layer, a FOX (Flowable Oxide) layer, a TOSZ (Tonen SilaZene) layer, a SOG (Spin On Glass) layer, a USG (Undoped Silica Glass) layer, a TEOS (Tetraethyl Ortho Silicate) layer, and an LTO (Low Temperature Oxide) layer, or a combination thereof.
